(19) United States
(12) Patent Application Publication
(10) Pub. No.: US 2026/0153553 A1
(43) Pub. Date: Jun. 4, 2026

(54) METHOD FOR DETECTING AC AND DC ARC FAULTS BASED ON ROGOWSKI COIL MAGNETIC COUPLING RESONANCE

(71) Applicant: FUJIAN TONGLI INTELLIGENT MACHINERY TECHNOLOGY CO., LTD., Fuzhou (CN)

(72) Inventors: Xin ZHENG, Fuzhou (CN); Yaozong WANG, Fuzhou (CN); Rongjun WU, Fuzhou (CN)

(73) Assignee: FUJIAN TONGLI INTELLIGENT MACHINERY TECHNOLOGY CO., LTD., Fuzhou (CN)

(21) Appl. No.: 19/460,385

(22) Filed: Jan. 27, 2026

Related U.S. Application Data
(63) Continuation of application No. PCT/CN2025/111062, filed on Jul. 29, 2025.

(30) Foreign Application Priority Data
Oct. 11, 2024 (CN) 202411412832.4

(51) Int. Cl. G01R 31/16; G01R 31/14

(52) U.S. Cl. CPC G01R 31/16; G01R 31/14

(57) ABSTRACT

The provided is a method for detecting AC and DC arc faults based on Rogowski coil magnetic coupling resonance, where a line to be detected passes through a uniformly wound Rogowski coil, and by adjusting the dimensions of the framework structure, the number of winding turns, and the values of a parallel-connected inductor and capacitor, a specified resonant frequency is obtained; when an arc fault occurs in the line to be detected, the Rogowski coil amplifies the characteristic frequency band signal corresponding to the resonant frequency by means of magnetic coupling resonance, so as to detect an arc fault state.

### CROSS-REFERENCE TO THE RELATED APPLICATIONS

This application is a continuation application of International Application No. PCT/CN2025/111062, filed on Jul. 29, 2025, which is based upon and claims priority to Chinese Patent Application No. 202411412832.4, filed on Oct. 11, 2024, the entire contents of which are incorporated herein by reference.

### TECHNICAL FIELD

The present invention belongs to the technical field of alternating-current (AC) and direct-current (DC) arc fault detection and specifically relates to a method for detecting AC and DC arc faults based on Rogowski coil magnetic coupling resonance.

### BACKGROUND

In recent years, with the technological development and progress of the low-voltage power distribution and utilization industry, system scale as well as voltage and current levels have gradually increased, cable structures have become increasingly complex, and potential line safety risks have correspondingly risen. An arc fault is a gaseous free-discharge phenomenon caused by air breakdown due to factors such as insulation aging or damage in electrical lines or devices, loose electrical connections, humid air, or a rapid increase in voltage or current, and is an important inducement of electrical fires. Generally, a series arc fault is connected in series within an electrical line, and its impedance reduces the operating current of the load. Therefore, conventional overcurrent protection apparatuses do not actuate to disconnect the fault circuit. For a parallel arc fault, the fault current is related to the impedance of the fault loop. When the line impedance is relatively high, the fault current is relatively small, and conventional circuit protection apparatuses likewise do not respond to it. Since sustained arc fault combustion generates a relatively high temperature, continuous arc combustion often leads to the occurrence of electrical fires. Therefore, designing an arc fault detection apparatus with low cost and high efficiency is of great significance for preventing electrical fires and protecting life and property safety.

At present, arc fault detection methods are mainly based on detecting electromagnetic wave signals, acoustic signals, optical signals, thermal signals, high-frequency currents, and the like associated with arc generation. Due to the diversity and randomness of arc faults as well as the uncertainty of their occurrence locations, detection of acoustic, optical, thermal, and other signals requires an increased number of sensors and detection positions, resulting in increased detection and system maintenance costs. Voltage and current are electrical quantities that are readily available in conventional power distribution line protection systems; therefore, existing arc fault detection methods mainly achieve detection by identifying fault characteristics in current or voltage. From the perspective of current characteristics, existing detection methods mostly utilize characteristics such as zero-crossing singularity, waveform similarity, harmonic content, high-frequency content, and rise rate of a current to construct fault criteria. Since the high-frequency signal characteristics under normal and fault conditions differ significantly, arc fault identification based on high-frequency signal characteristics has been widely applied. However, conventional current transformers are prone to magnetic core saturation under large current conditions, resulting in increased measurement errors, and also exhibit significant bandwidth limitations in high-frequency current environments. Due to their design principles and the characteristics of magnetic core materials, the response frequency range of transformers is usually limited, making it difficult to accurately capture subtle variations in high-frequency signals. Rapid variations in high-frequency currents may cause signal distortion or attenuation, thereby affecting the accuracy and reliability of fault detection, which is particularly prominent when high-frequency arc faults need to be monitored. Also, under the influence of nonlinear loads, it is often difficult for a single characteristic to satisfy the requirements of fault detection for multiple load types. Consequently, multi-characteristic fusion techniques based on machine learning and deep learning technologies have attracted increasing attention from researchers in recent years. However, deploying complex algorithms on embedded hardware apparatuses faces challenges such as computational capability, storage space, power consumption, and real-time performance. Hardware resources are usually constrained, and complex algorithms may exceed their capacity. In addition, algorithmic energy consumption and execution time must also be considered to ensure system efficiency and real-time performance.

### SUMMARY

In view of the numerous defects and deficiencies existing in the prior art solutions, the present invention utilizes the principle of magnetic coupling resonance, in combination with the advantages of a Rogowski coil sensor such as big bandwidth and absence of magnetic saturation, performs parallel connection of inductors and capacitors with different values by means of impedance matching, and increases the frequency adjustable range, thereby realizing resonant amplification of signals in the characteristic frequency bands of arc faults and effectively extracting specific high-frequency components in the line current. Unlike conventional Rogowski coil sensors combined with integrators for line current measurement, this combination not only enhances the response of high-frequency signals, but also effectively filters out low-frequency noise, further expanding the bandwidth and improving the signal-to-noise ratio. In the monitoring of arc faults or other high-frequency currents, the synergistic effect of magnetic coupling resonance and the Rogowski coil helps to improve the sensitivity and reliability of the detection system, thereby realizing detection of both AC and DC arc faults.

The technical solution specifically adopted by the present invention to solve the technical problems is as follows:

A method for detecting AC and DC arc faults based on Rogowski coil magnetic coupling resonance, wherein a line to be detected passes through a uniformly wound Rogowski coil, and by adjusting the dimensions of the framework structure, the number of winding turns, and the values of a parallel-connected inductor and capacitor, a specified resonant frequency is obtained; when an arc fault occurs in the line to be detected, the Rogowski coil amplifies the characteristic frequency band signal corresponding to the resonant frequency by means of magnetic coupling resonance, so as to detect an arc fault state.

Further, whether an arc fault occurs is determined according to a comparison between a preset threshold and the acquired characteristic frequency band signal.

Further, when the detected signal exceeds the threshold, after waiting for a first duration, if a signal exceeding the threshold is detected again within a subsequent second duration, an arc fault may occur in the line and zero-crossing rate calculation is initiated: starting from the first signal exceeding the threshold, a zero-crossing rate of a signal within a third duration is calculated; moreover, only the zero-crossing rate ZCR of a signal with an amplitude exceeding a given value is calculated; if 0.002<ZCR<0.02, it is determined that an arc fault occurs in the line to be detected; if not within the range, then if a signal exceeds the threshold within a subsequent fourth duration, a zero-crossing rate of a signal within the third duration is calculated again and arc fault determination is performed; if no signal exceeds the threshold within the fourth duration, it is determined that no arc fault occurs in the line.

The zero-crossing rate ZCR is calculated according to the following formula:

$$zcr = \frac{{\sum }_{n = 2}^{T} II \{ {s}_{n} {s}_{n - 1} < 0 \}}{T}$$

wherein s is a signal with a length of T, and the function ∥{A} is 1 when parameter A is true, and is 0 otherwise.

Moreover, a sensor for detecting AC and DC arc faults based on Rogowski coil magnetic coupling resonance, comprising: a uniformly wound Rogowski coil, and an inductor and/or capacitor connected in parallel across two ends of the Rogowski coil; by adjusting the dimensions of the framework structure, the number of winding turns, and the values of the parallel-connected inductor and capacitor, a specified resonant frequency is obtained; a line to be detected passes through the Rogowski coil, and when an arc fault occurs in the line to be detected, the Rogowski coil amplifies the characteristic frequency band signal corresponding to the resonant frequency by means of magnetic coupling resonance, so as to detect an arc fault state.

Further, different inductors and/or capacitors are connected in parallel by means of impedance matching, so as to increase the frequency adjustable range.

Moreover, an apparatus for detecting AC and DC arc faults based on Rogowski coil magnetic coupling resonance, comprising the sensor described above, wherein the sensor is connected to a microcontroller; the microcontroller determines whether an arc fault occurs according to a preset threshold and the characteristic frequency band signal acquired by the sensor.

Further, when the signal detected by the microcontroller exceeds the threshold, after waiting for a first duration, if a signal exceeding the threshold is detected again within a subsequent second duration, an arc fault may occur in the line and zero-crossing rate calculation is initiated: starting from the first signal exceeding the threshold, a zero-crossing rate of a signal within a third duration is calculated; moreover, only the zero-crossing rate ZCR of a signal with an amplitude exceeding a given value is calculated; if 0.002<ZCR<0.02, it is determined that an arc fault occurs in the line to be detected; if not within the range, then if a signal exceeds the threshold within a subsequent fourth duration, a zero-crossing rate of a signal within the third duration is calculated again and arc fault determination is performed; if no signal exceeds the threshold within the fourth duration, it is determined that no arc fault occurs in the line.

The zero-crossing rate ZCR is calculated according to the following formula:

$$zcr = \frac{{\sum }_{n = 2}^{T} II \{ {s}_{n} {s}_{n - 1} < 0 \}}{T}$$

wherein s is a signal with a length of T, and the function ∥{A} is 1 when parameter A is true, and is 0 otherwise.

Compared with the prior art, the present invention and preferred embodiments thereof utilizes the principle of magnetic coupling resonance, in combination with the advantages of a Rogowski coil sensor such as big bandwidth and absence of magnetic saturation, performs parallel connection of inductors and capacitors with different values by means of impedance matching, and increases the frequency adjustable range, thereby realizing resonant amplification of signals in the characteristic frequency bands of arc faults and effectively extracting specific high-frequency components in the line current. Unlike conventional Rogowski coil sensors combined with integrators for line current measurement, this combination not only enhances the response of high-frequency signals, but also effectively filters out low-frequency noise, further expanding the bandwidth and improving the signal-to-noise ratio. In the monitoring of arc faults or other high-frequency currents, the synergistic effect of magnetic coupling resonance and the Rogowski coil helps to improve the sensitivity and reliability of the detection system, thereby realizing detection of both AC and DC arc faults.

### BRIEF DESCRIPTION OF THE DRAWINGS

The present invention is further described in detail below in conjunction with the accompanying drawings and specific embodiments:

FIG. 1 is a schematic diagram of a Rogowski coil structure and the principle of the solution of the present invention;

FIG. 2 is a schematic diagram of the connection between the Rogowski coil and a circuit according to an embodiment of the present invention;

FIG. 3 is a flowchart of the arc fault algorithm according to an embodiment of the present invention.

### DETAILED DESCRIPTION OF THE EMBODIMENTS

To make the features and advantages of this patent more apparent and readily understandable, specific embodiments are set forth below and described in detail.

It should be noted that the following detailed description is exemplary and is intended to provide further explanation of the present application. Unless otherwise specified, all technical and scientific terms used herein have the same meanings as those commonly understood by a person of ordinary skill in the technical field to which the present application belongs.

It should be noted that the terminology used herein is for the purpose of describing specific embodiments only and is not intended to limit the exemplary embodiments of the present application. As used herein, unless the context clearly indicates otherwise, the singular forms are intended to include the plural forms as well. In addition, it should be understood that when the terms “comprise” and/or “include” are used in this specification, they indicate the presence of stated features, steps, operations, devices, components, and/or combinations thereof.

The solution of the present invention is specifically described below by way of an embodiment.

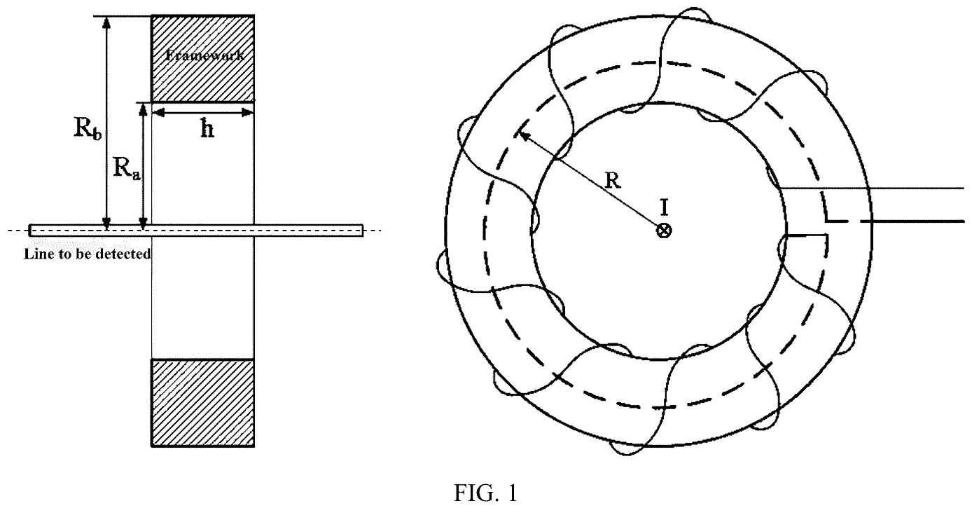

The structure of the Rogowski coil is shown in FIG. 1. The Rogowski coil has no iron core. At low frequencies, the induced signal is very weak, and its output is proportional to the rate of change of the current. Since low-frequency currents vary slowly, the signal amplitude is correspondingly small. At high frequencies, however, the Rogowski coil exhibits improved response performance, being capable of inducing relatively large voltage signals and accurately capturing subtle variations in high-frequency currents. In addition, because the Rogowski coil does not include a magnetic core structure, magnetic saturation phenomenon is avoided, thereby providing wide bandwidth and relatively high signal accuracy in high-frequency applications, which is suitable for detection scenarios such as high-frequency arc faults. Magnetic coupling resonance amplifies current signals at the resonant frequency, enabling the Rogowski coil to more effectively sense current variations at a specific frequency, thereby functioning in a manner similar to a band-pass filter.

Conventional Rogowski coil sensors must be used in combination with an integrator and are mainly applied to sensing and measuring current signals within a wide frequency band range, which lack frequency selectivity and therefore require subsequent algorithmic processing to extract current characteristic signals.

In the solution designed in the present invention, the Rogowski coil sensor no longer needs to be used together with an integrator. Instead, magnetic coupling resonance is utilized to realize the function of a band-pass filter, specifically extracting and amplifying signals of a specific frequency band in the fault current. According to the characteristic frequency bands of DC and AC arc faults, by adjusting the number of turns and the dimensions of the framework of the Rogowski coil and connecting an inductor or capacitor of specific values in parallel at two ends of the coil, and by changing the internal parameters of the coil by means of an impedance matching method, the resonant frequency of the coil can be adjusted to the fault characteristic frequency band, thereby directly and effectively extracting the current components of the frequency band and achieving efficient detection and amplification of arc fault characteristic signals.

Due to limitations in their operating principles, conventional Rogowski coil sensors require combined use of an integrator for signal processing and therefore can only be applied in AC scenarios, being incapable of detecting DC faults. In contrast, the present invention adopts the principle of magnetic coupling resonance to amplify signals of a specific frequency band. Even in DC scenarios, when an arc fault occurs, the fault signal of a corresponding frequency band can also be accurately captured. Therefore, the present invention is applicable not only to AC fault detection but also to effective monitoring of DC faults, thereby providing broad versatility and adaptability in AC and DC arc fault detection.

When a line to be detected operates normally, the frequency components of the current thereof are typically the MHz level or less and do not generate significant high-frequency signals. However, during an arc fault, prominent high-frequency signals are generated, with frequencies usually far exceeding the current frequencies when a line operates normally. Accordingly, by adjusting the dimensions of the framework and the values of the parallel-connected inductor and capacitor to adjust the resonant frequency of the Rogowski coil so that it specifically responds to high-frequency signals of arc faults, and normal operating states can be effectively distinguished from arc fault states.

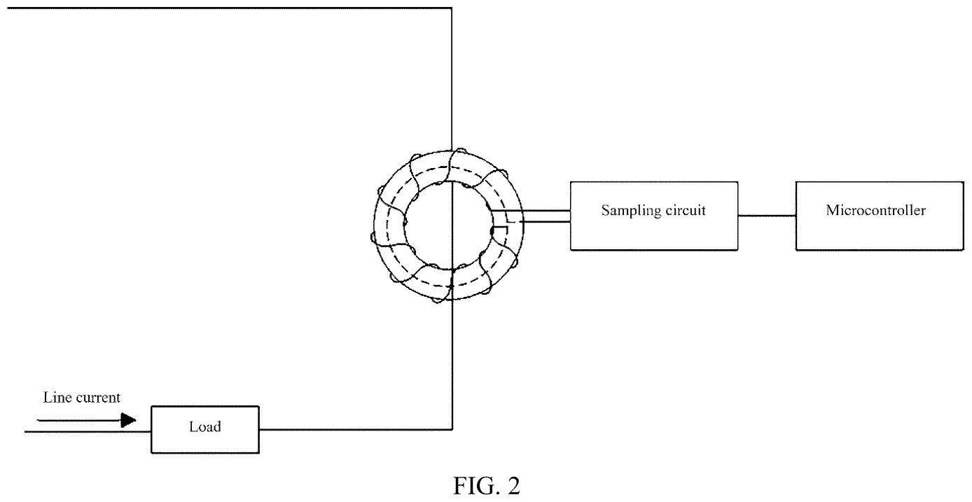

The natural resonant frequency of the Rogowski coil is mainly determined by the dimensions of the framework and the number of winding turns. Taking as an example a uniformly wound Rogowski coil having Ra=8.5 mm, Rb=24 mm, h=15 mm, and 105 turns, the resonant frequency can reach 3 MHz. By means of the connection configuration shown in FIG. 2, frequency signals outside a specific frequency band (around the resonant frequency) can be effectively filtered out, enabling effective extraction of high-frequency components of a specific frequency band in the line current. A microcontroller can then be used to detect and identify the acquired signals by means of a sampling circuit, thereby realizing arc fault detection and determination.

The objective of the present invention is to utilize the advantages of the Rogowski coil sensor of wide bandwidth and absence of magnetic saturation, in combination with the principle of magnetic coupling resonance, to extract specific high-frequency components in line current signals for detecting and identifying whether an arc fault occurs in the line. The implementation of the solution mainly includes two modules:

(1) Sensor detection module: For a uniformly wound Rogowski coil as shown in FIG. 1, by adjusting the dimensions of the framework structure, the number of winding turns, and the values of the parallel-connected inductor and capacitor according to practical requirements, different resonant frequencies can be achieved. As shown in FIG. 2, the line to be detected passes through the coil. When the line to be detected operates normally, the induced signal of the Rogowski coil is very small and nearly zero. However, when an arc fault occurs in the line to be detected, a large number of high-frequency signals will appear in the line, and the coil amplifies the characteristic frequency band signal by means of magnetic coupling resonance. In this manner, the sensor can effectively detect the arc fault state.

(2) Algorithm module: Due to the frequency of the high-frequency signals generated by arc faults and limitations in microcontroller performance, the signal sampling rate is insufficient to precisely capture the high-frequency signals and process them in real time. Some key high-frequency signal characteristics may not be detected in a timely or accurate manner. Therefore, to improve detection reliability, zero-crossing rate calculation is added on the basis of signal threshold determination. The zero-crossing rate (zcr) calculation formula is as shown below.

$$zcr = \frac{{\sum }_{n = 2}^{T} II \{ {s}_{n} {s}_{n - 1} < 0 \}}{T}$$

s is a signal with a length of T (number of sampling points), and the function ∥{A} is 1 when parameter A is true, and is 0 otherwise.

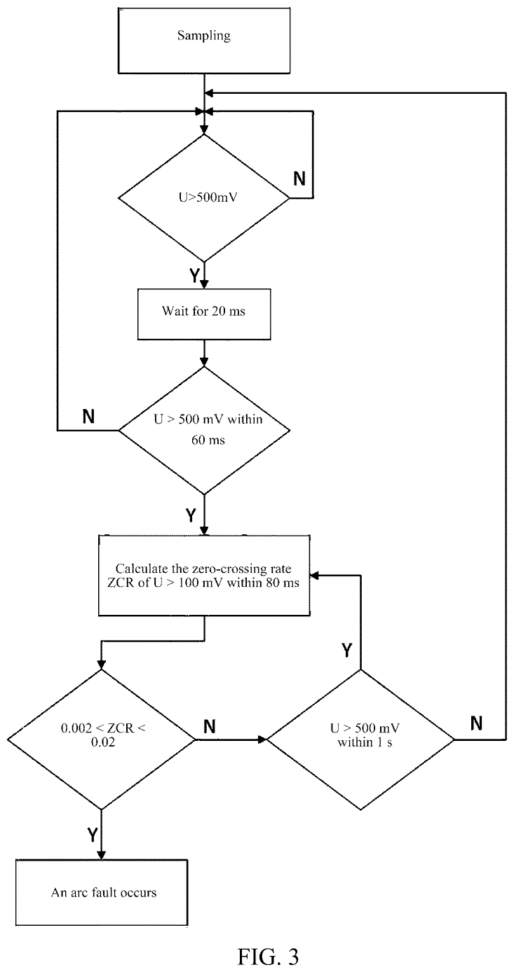

The algorithm flowchart is as shown in FIG. 3, taking a sampling rate of 100 kHz as an example (the thresholds in the figure can be adjusted according to actual conditions). When the microcontroller detects a signal exceeding the threshold, in order to avoid interference caused by normal operating conditions such as appliance connection or switching actions, a delay of 20 ms is applied. If, within the subsequent 60 ms, another signal exceeding the threshold is detected, an arc fault may be present in the line, and ZCR calculation is initiated. Starting from the first signal exceeding the threshold, the zero-crossing rate (ZCR) of the signal within 80 ms is calculated. To avoid interference, only the zero-crossing rate of a signal with an amplitude exceeding 100 mV is calculated; if 0.002<ZCR<0.02, it is determined that an arc fault occurs in the line to be detected; if not within the range, then if a signal exceeds the threshold within the next 1 s, the zero-crossing rate of a signal within 80 ms is calculated again and arc fault determination is performed; if no signal exceeds the threshold within 1 s, it is determined that no arc fault occurs in the line.

It should be noted that, unless otherwise defined, the technical or scientific terms used in the present invention shall have their usual meaning as understood by those of ordinary skill in the art to which the present invention pertains. The “first”, “second”, and similar words used in the present invention do not imply any specific order, quantity, or importance but are merely used to distinguish different components. The “include” or “comprise” and similar words indicate that the components or objects preceding the word encompass those listed after the word and their equivalents, but do not exclude other components or objects. The “connect” or “couple” and similar words are not limited to physical or mechanical connections, but may include electrical connections, whether direct or indirect. The “up”, “down”, “left”, “right”, and similar words are used solely to represent relative positional relationships. When the absolute position of the described object changes, the relative positional relationship may also change accordingly.

The above are merely preferred embodiments of the present invention and do not constitute other limitations of the present invention. Any person skilled in the art may take advantage of the disclosed technical content described above to change or modify it to equivalent embodiments with equivalent variations. However, any simple modifications, equivalent changes, or variations made based on the technical essence of the present invention to the above embodiments, without departing from the content of the technical solution of the present invention, still fall within the protection scope of the technical solution of the present invention.

This patent is not limited to the best embodiment described above. Anyone inspired by this patent may develop other forms of a method for detecting AC and DC arc faults based on Rogowski coil magnetic coupling resonance. Any equivalent changes or modifications made within the scope of the present invention shall be covered by this patent.

What is claimed is:

1. A method for detecting alternating-current (AC) and direct-current (DC) arc faults based on Rogowski coil magnetic coupling resonance, wherein a line to be detected passes through a Rogowski coil uniformly wound, and by adjusting dimensions of a framework structure, number of winding turns, and values of a parallel-connected inductor and capacitor, a resonant frequency is obtained; when an arc fault occurs in the line to be detected, the Rogowski coil amplifies a characteristic frequency band signal corresponding to the resonant frequency by means of magnetic coupling resonance to detect an arc fault state.

2. The method for detecting the AC and DC arc faults based on the Rogowski coil magnetic coupling resonance according to claim 1, wherein whether the arc fault occurs is determined according to a comparison between a preset threshold and the characteristic frequency band signal.

3. The method for detecting the AC and DC arc faults based on the Rogowski coil magnetic coupling resonance according to claim 2, wherein when a detected signal exceeds the preset threshold, after waiting for a first duration, when a signal exceeding the preset threshold is detected again within a subsequent second duration, the arc fault occurs in the line and zero-crossing rate calculation is initiated: starting from a first signal exceeding the preset threshold, a zero-crossing rate of a signal within a third duration is calculated; only the zero-crossing rate ZCR of a signal with an amplitude exceeding a given value is calculated; when 0.002<ZCR <0.02, it is determined that the arc fault occurs in the line to be detected; when 0.002<ZCR <0.02 is not met, and when a signal exceeds the preset threshold within a subsequent fourth duration, the zero-crossing rate of the signal within the third duration is calculated again and arc fault determination is performed; when no signal exceeds the preset threshold within the subsequent fourth duration, it is determined that no arc fault occurs in the line.

4. The method for detecting the AC and DC arc faults based on the Rogowski coil magnetic coupling resonance according to claim 3, wherein the zero-crossing rate ZCR is calculated according to following formula:
$$zcr = \frac{{\sum }_{n = 2}^{T} II \{ {s}_{n} {s}_{n - 1} < 0 \}}{T}$$
wherein s is a signal with a length of T, and a function ∥{A} is 1 when parameter A is true, and is 0 when the parameter A is not true.

5. A sensor for detecting AC and DC arc faults based on Rogowski coil magnetic coupling resonance, comprising: a Rogowski coil uniformly wound, and an inductor and/or capacitor connected in parallel across two ends of the Rogowski coil, wherein by adjusting dimensions of a framework structure, number of winding turns, and values of a parallel-connected inductor and capacitor, a resonant frequency is obtained; a line to be detected passes through the Rogowski coil, and when an arc fault occurs in the line to be detected, the Rogowski coil amplifies a characteristic frequency band signal corresponding to the resonant frequency by means of magnetic coupling resonance to detect an arc fault state.

6. The sensor for detecting the AC and DC arc faults based on the Rogowski coil magnetic coupling resonance according to claim 5, wherein different inductors and/or capacitors are connected in parallel by means of impedance matching to increase a frequency adjustable range.

7. An apparatus for detecting AC and DC arc faults based on Rogowski coil magnetic coupling resonance, comprising the sensor according to claim 5, wherein the sensor is connected to a microcontroller; the microcontroller determines whether the arc fault occurs according to a preset threshold and the characteristic frequency band signal acquired by the sensor.

8. The apparatus for detecting the AC and DC arc faults based on the Rogowski coil magnetic coupling resonance according to claim 7, wherein when a signal detected by the microcontroller exceeds the preset threshold, after waiting for a first duration, when a signal exceeding the preset threshold is detected again within a subsequent second duration, the arc fault occurs in the line and zero-crossing rate calculation is initiated: starting from a first signal exceeding the preset threshold, a zero-crossing rate of a signal within a third duration is calculated; only the zero-crossing rate ZCR of a signal with an amplitude exceeding a given value is calculated; when 0.002<ZCR <0.02, it is determined that the arc fault occurs in the line to be detected; when 0.002<ZCR <0.02 is not met, and when a signal exceeds the preset threshold within a subsequent fourth duration, a zero-crossing rate of a signal within the third duration is calculated again and arc fault determination is performed; when no signal exceeds the preset threshold within the fourth duration, it is determined that no arc fault occurs in the line.

9. The apparatus for detecting the AC and DC arc faults based on the Rogowski coil magnetic coupling resonance according to claim 8, wherein the zero-crossing rate ZCR is calculated according to the following formula:
$$zcr = \frac{{\sum }_{n = 2}^{T} II \{ {s}_{n} {s}_{n - 1} < 0 \}}{T}$$
wherein s is a signal with a length of T, and a function ∥{A} is 1 when parameter A is true, and is 0 when the parameter A is not true.

10. The apparatus for detecting the AC and DC arc faults based on the Rogowski coil magnetic coupling resonance according to claim 7, wherein in the sensor, different inductors and/or capacitors are connected in parallel by means of impedance matching to increase a frequency adjustable range.

11. The apparatus for detecting the AC and DC arc faults based on the Rogowski coil magnetic coupling resonance according to claim 10, wherein when a signal detected by the microcontroller exceeds the preset threshold, after waiting for a first duration, when a signal exceeding the preset threshold is detected again within a subsequent second duration, the arc fault occurs in the line and zero-crossing rate calculation is initiated: starting from a first signal exceeding the preset threshold, a zero-crossing rate of a signal within a third duration is calculated; only the zero-crossing rate ZCR of a signal with an amplitude exceeding a given value is calculated; when 0.002<ZCR <0.02, it is determined that the arc fault occurs in the line to be detected; when 0.002<ZCR <0.02 is not met, and when a signal exceeds the preset threshold within a subsequent fourth duration, a zero-crossing rate of a signal within the third duration is calculated again and arc fault determination is performed; when no signal exceeds the preset threshold within the fourth duration, it is determined that no arc fault occurs in the line.

12. The apparatus for detecting the AC and DC arc faults based on the Rogowski coil magnetic coupling resonance according to claim 11, wherein the zero-crossing rate ZCR is calculated according to the following formula:
$$zcr = \frac{{\sum }_{n = 2}^{T} II \{ {s}_{n} {s}_{n - 1} < 0 \}}{T}$$
wherein s is a signal with a length of T, and a function ∥{A} is 1 when parameter A is true, and is 0 when the parameter A is not true.
